(19) United States
(12) Patent Application Publication
(10) Pub. No.: US 2025/0125791 A1
(43) Pub. Date: Apr. 17, 2025

(54) METHOD FOR REALIZING SPEAKER ARRAY-ORIENTED MULTIPLE FILTER SYSTEM, DEVICE, AND COMPUTER-READABLE STORAGE MEDIUM

(71) Applicant: AAC Acoustic Technologies (Shanghai) Co., Ltd., Shanghai (CN)

(72) Inventors: Xuejing Sun, L.A., CA (US); Huan Ge, Shanghai (CN)

(21) Appl. No.: 18/536,278

(22) Filed: Dec. 12, 2023

Related U.S. Application Data
(63) Continuation of application No. PCT/CN2023/124231, filed on Oct. 12, 2023.

(51) Int. Cl. H03H 17/02; H03H 17/00; H04R 3/00

(52) U.S. Cl. CPC H03H 17/0289; H04R 3/00; H03H 2017/0081; H03H 2017/009

(57) ABSTRACT

The present disclosure provides a method for realizing a speaker array-oriented multiple filter system and a related device, belonging to the technical field of audio systems. The method includes: merging, before real-time audio processing, filters of a plurality of sound effect modules in an audio signal processing flow offline to form a finite impulse response (FIR) multiple filter network. The present disclosure places most of computation in an offline processing flow by merging the filters of the plurality of sound effect modules in offline convolution, so that the computation amount of real-time processing is greatly reduced.

### CROSS-REFERENCE TO RELATED APPLICATION

The present application is a continuation of PCT Patent Application No. PCT/CN2023/124231, filed Oct. 12, 2023, which is incorporated by reference herein in its entirety.

### TECHNICAL FIELD

The present disclosure relates to the field of audio systems, and in particular relates to a method for realizing a speaker array-oriented multiple filter system, a device, and a non-transitory computer-readable storage medium.

### BACKGROUND

The number of speakers used in an in-vehicle audio system solution is large. In addition to conventional sound post-processing algorithms (including equalization, gain, delay, etc.), there are also algorithms related to sound field control based on multi-speaker arrays that are utilized to achieve such special sound field control effects as global or local sound field optimization, independent sound zone playback, and the like.

Sound field control related algorithms for in-vehicle multi-speaker arrays include sound field control algorithms, independent sound zone control algorithms, simulated virtual acoustic scenarios (also known as virtual hall algorithms), speaker compensation algorithms, and the like.

The sound field control algorithm, also known as a sound field correction or sound field compensation algorithm, performs a filtering operation (such as a convolution operation of a finite impulse response (FIR) filter) on input signals of multiple channels through a design of a filter network for each speaker in a multi-speaker array, to achieve global or local sound field optimization effect.

The independent sound zone control algorithm, similar to the sound field control algorithm, also designs the filter network for each speaker in the multi-speaker array, and performs the filtering operation on the input signals of multiple channels. The difference between the independent sound zone control algorithm and the sound field control algorithm is that an objective of the design of the filter in the independent sound zone control algorithm is to maximize a ratio of sound energy of one or more specified regions to sound energy of other regions, in order to achieve a purpose of partition control.

The simulated virtual acoustic scenario, also known as the virtual hall algorithm, also requires similar operations.

The speaker compensation algorithm, i.e., compensation for physical characteristics of the speakers themselves, such as nonlinear distortion compensation, is also realized by performing the filtering operation for each speaker in the multi-speaker array.

As shown in FIG. 1, in-vehicle sound processing in the current in-vehicle audio system is sequentially processing audio signal streams in accordance with sound modules, the processing and decoupling between the sound modules not interfering with each other, which is specifically described as follows.

A sound field control module is responsible for cooperative work of multiple speakers in the vehicle to avoid poor response of the speakers in the vehicle caused by phase mismatch and other problems, resulting in a poor sense of hearing.

An independent sound zone control module is configured to realize partition playback function of the in-vehicle audio, such as a particular music is played only in a main driving position, and other positions are not affected, or different contents are played in different positions, and different positions do not affect each other.

A convolution reverb module is configured to convolve played audio contents with impulse response (IR) of a specific scenario (e.g., a concert hall, a stadium, etc.), in order to simulate the sound effect of the concert hall or the like in an in-vehicle environment.

A speaker compensation module is configured to improve and compensate frequency response performance defects of the speaker itself as well as frequency response defects of the speaker in the in-vehicle environment due to spatial reflections and other reasons.

The sound field control algorithm used in the sound field control module and the independent sound zone control algorithm used in the independent sound zone control module are both based on measurements of the in-vehicle sound field, and then to use the algorithm to simulate and calculate the filter coefficients for each speaker. Because the FIR filter is stable and easy to design and implement, the sound field control algorithm and the independent sound zone control algorithm generally use FIR filters for the design of the filter network.

The convolution reverb module uses convolution reverb technology such as the virtual hall algorithm and the like to pass the input audio signal through the filter constituted by impulse response of a target acoustic space, to achieve restoration effect of a virtual acoustic space. The impulse response of the acoustic space is generally obtained by actual measurements and can be used directly as the FIR filter.

However, although FIR filters are stable and easy to design and implement, a high order is required to restore and simulate low-frequency acoustic reflections in acoustic spaces such as in-vehicle spaces or virtual halls. For example, for response compensation of a general woofer speaker in the vehicle, a FIR filter with an order of more than 10,000 orders is required, and for simulation of the virtual hall IR, a FIR filter with tens of thousands or even longer of orders may be required for the simulation.

In response to the above, Applicant of the present disclosure found that if the conventional algorithm processing is carried out in the form of independent sound effect modules, a multi-stage complex filter system requires a very high amount of computation when effects of multiple sound effect modules are required to take effect at the same time, which is difficult for conventional in-vehicle digital signal processing (DSP) to withstand.

### SUMMARY

The present disclosure provides a method for realizing a speaker array-oriented multiple filter system and a related device, for simplifying computation of audio real-time processing. The technical solutions are as follows.

A first aspect of the present disclosure provides a method for realizing a speaker array-oriented multiple filter system, including: merging, before real-time audio processing, filters of a plurality of sound effect modules in an audio signal processing flow offline to form a finite impulse response (FIR) multiple filter network.

As an improvement, the method further includes: intercepting, with respect to the FIR multiple filter network, first N points of a FIR sequence of the FIR multiple filter network to obtain a new FIR filter, where the FIR sequence of the FIR multiple filter network has a length of L, and N and L are both positive integers; and employing an infinite impulse response (IIR) network to fit last L-N points of the FIR sequence of the FIR multiple filter network; where the new FIR filter and the IIR network collectively accomplish equivalent filtering of the FIR sequence of the FIR multiple filter network.

As an improvement, the N is determined based on characteristics of the FIR sequence of the FIR multiple filter network, and the N satisfies following requirements: with respect to the first N points of the FIR sequence, retained high-frequency components of the FIR sequence of the FIR multiple filter network satisfying a first predetermined condition; and with respect to the last L-N points of the FIR sequence, retained low-frequency components of the FIR sequence of the FIR multiple filter network satisfying a second predetermined condition.

As an improvement, the IIR network includes cascaded second-order IIR or parallel second-order IIR.

As an improvement, the method further includes determining an offline processing mode of the FIR multiple filter network based on a type of a speaker to which an audio channel is connected.

As an improvement, the type of the speaker includes a midrange speaker, a woofer-subwoofer speaker and a tweeter speaker; and the determining the offline processing mode of the FIR multiple filter network based on the type of the speaker to which the audio channel is connected includes: in response to the audio channel being connected to the midrange speaker, converting the FIR multiple filter network offline into a form of a FIR filter plus a IIR filter network; in response to the audio channel being connected to the woofer-subwoofer speaker, performing offline low-pass filtering on a FIR filter corresponding to a woofer channel in the FIR multiple filter network, and using a cascaded or parallel second-order IIR filter network for fitting; and in response to the audio channel being connected to the tweeter speaker, performing offline high-pass filtering and windowed truncation on a FIR filter corresponding to a tweeter channel in the FIR multiple filter network.

As an improvement, the plurality of sound effect modules includes at least one of a sound field control module, an independent sound zone control module, a convolution reverb module, and a speaker compensation module.

A second aspect of the present disclosure provides an apparatus for realizing a speaker array-oriented multiple filter system, including: an offline merging processing module for merging, before real-time audio processing, filters of a plurality of sound effect modules in an audio signal processing flow offline to form a finite impulse response (FIR) multiple filter network.

A third aspect of the present disclosure provides a device including a transceiver, a memory, a processor and a computer program stored on the memory and executable on the processor, where the processor executes the computer program to perform the method for realizing the speaker array-oriented multiple filter system according to the first aspect.

A fourth aspect of the present disclosure provides computer-readable storage medium storing a computer program, where the computer program when executed by a processor causes the processor to perform the method for realizing the speaker array-oriented multiple filter system according to the first aspect.

The beneficial effects of the above technical solution of the present disclosure are as follows.

Embodiments of the present disclosure provide a method for realizing a speaker array-oriented multiple filter system and a related device, in which filters of a plurality of sound effect modules in an audio signal processing flow are merged offline before real-time audio processing to form a FIR multiple filter network. The present disclosure places most of the computation in the offline processing flow by offline convolutional merging of the filters of the plurality of sound effect modules, so that the computation amount of the real-time processing is greatly reduced.

### BRIEF DESCRIPTION OF THE DRAWINGS

FIG. 1 shows a schematic diagram of a signal processing flow of a speaker array in an in-vehicle sound processing flow of an existing in-vehicle audio system.

FIG. 2 shows a schematic diagram of implementation logic of merging high-order filters of a plurality of modules offline to form a multiple filter network in an embodiment of the present disclosure.

FIG. 3 shows a schematic diagram of implementation logic of equivalenting a high-order FIR filter to a combination of a low-order FIR filter and an IIR filter network.

FIG. 4 shows a schematic diagram of implementation logic of offline optimization of the FIR filter for a midrange speaker channel in an embodiment of the present disclosure.

FIG. 5 shows a schematic diagram of implementation logic of offline optimization of the FIR filter for woofer/subwoofer speaker channels in an embodiment of the present disclosure.

FIG. 6 shows a schematic diagram of implementation logic of offline optimization of the FIR filter for a tweeter channel in an embodiment of the present disclosure.

FIG. 7 shows a schematic structural diagram of an apparatus for realizing a speaker array-oriented multiple filter system in an embodiment of the present disclosure.

FIG. 8 shows a schematic structure of a device in an embodiment of the present disclosure.

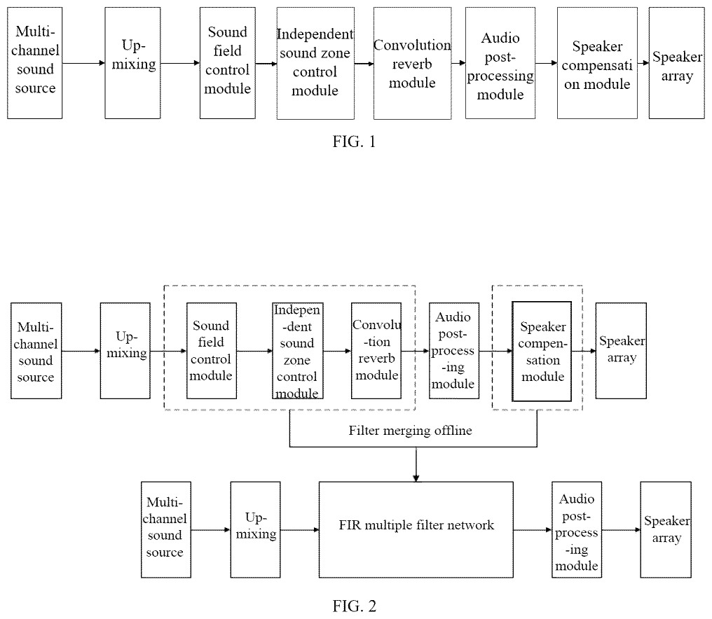

### DETAILED DESCRIPTION OF THE EMBODIMENTS

In order to make the technical problems, technical solutions and advantages of the present disclosure clearer, the following description will be provided in detail with reference to the accompanying drawings and embodiments. In the following description, particular details such as specific configurations and components are provided only to facilitate full understanding of embodiments of the present disclosure. Accordingly, it should be clear to those skilled in the art that various changes and modifications are able to be made to the embodiments described herein without departing from the scope and spirit of the present disclosure. In addition, descriptions of known functions and constructions have been omitted for the sake of clarity and brevity.

It should be understood that phases throughout the specification to ‘an embodiment’ or ‘one embodiment’ imply that particular features, structures or characteristics associated with the embodiment are included in at least one embodiment of the present disclosure. Therefore, ‘in an embodiment’ or ‘in one embodiment’ appearing at various places throughout the specification may not necessarily refer to the same embodiment. Furthermore, these particular features, structures or characteristics may be combined in one or more embodiments in any suitable manner.

In various embodiments of the present disclosure, it should be understood that magnitudes of serial numbers of various processes described below does not imply an order of execution of these processes, and that the order of execution of the processes should be determined by their functions and internal logic, without constituting any limitation on the implementation of the processes in the embodiments of the present disclosure.

Applicant of the present disclosure has found that the sound field control algorithm, the independent sound zone control algorithm, the virtual hall algorithm, and the speaker compensation algorithm share a series of similarities. 1. These algorithms all perform filtering for each speaker in a speaker array. 2. The filters used in these algorithms need to be obtained in advance through measurement, modeling, and computation prior to the real-time audio processing. The filters are strongly correlated with a spatial structure of the vehicle, a layout of the speaker, characteristics of the speaker itself, and characteristics of a target acoustic space (hall) itself, and thus these filters themselves will not change after the filters are obtained by modeling.

Based on the above two points, the present disclosure innovatively provides a method for realizing a speaker array-oriented multiple filter system, in which the filters of a plurality of sound modules in an audio signal processing flow are merged offline before real-time audio processing, to form a FIR multiple filter network and simplify final audio real-time processing computation.

It should be noted that real-time audio processing refers to when using electronic devices such as computers or cell phones to play audio, if the audio is required to be processed, such as adding some sound effects, sound effects processing needs to be performed at the same time as the audio is played. In practice, the sound field control algorithm, the independent sound zone control algorithm, the virtual hall algorithm, and the speaker compensation algorithm utilize specific filters to achieve real-time processing of audio streams (e.g., real-time processing of sound effects for audio streams). It should be noted, however, that acquisition of parameters of these specific filters is independent of audio playback itself, but needs to be designed in advance through additional processes of measurement, modeling, and computation.

In response to this, as shown in FIG. 2, the present disclosure merges these filters such as a sound field control filter of the sound field control module, an independent sound zone control filter of the independent sound zone control module, a convolution reverb filter of the convolution reverb module, and a speaker compensation filter of the speaker compensation module, offline in advance in the audio signal processing flow, to form a FIR multiple filter network. The present disclosure places most of the computation in the offline processing flow by offline convolutional merging of the filters of the plurality of sound modules, thereby greatly reducing the computation amount of real-time processing.

An order of the FIR multiple filter network obtained after offline merging is generally high. In real-time processing, for high-order FIR filtering, a conventional practice is to use non-uniformly partitioned FFT-based convolution for filtering processing, reducing the computation amount of real-time processing. Embodiments of the present disclosure further provide an offline processing method capable of reducing the computation amount of a high-order FIR multiple filter network with respect to the FIR multiple filter network obtained after offline merging.

In general, based on sound waves and their associated physical properties of propagation, reflection and absorption in space, IR sequences of speakers in space all exhibit essentially the same characteristics, i.e., mid-and high-frequency components are relatively concentrated in the front of the sequence and decay to a sufficiently small size in a relatively short period of time, whereas a low-frequency component decay very slowly and takes a very long time to decay to a sufficiently small size. A longer trailing tail in the FIR filter is generally caused by low-frequency resonance and contains only the low-frequency component. Based on this property, embodiments of the present disclosure split FIR filters with characteristics similar to speaker IR as well as having a relatively high order, into a combination of FIR+IIR (i.e., infinite impulse response).

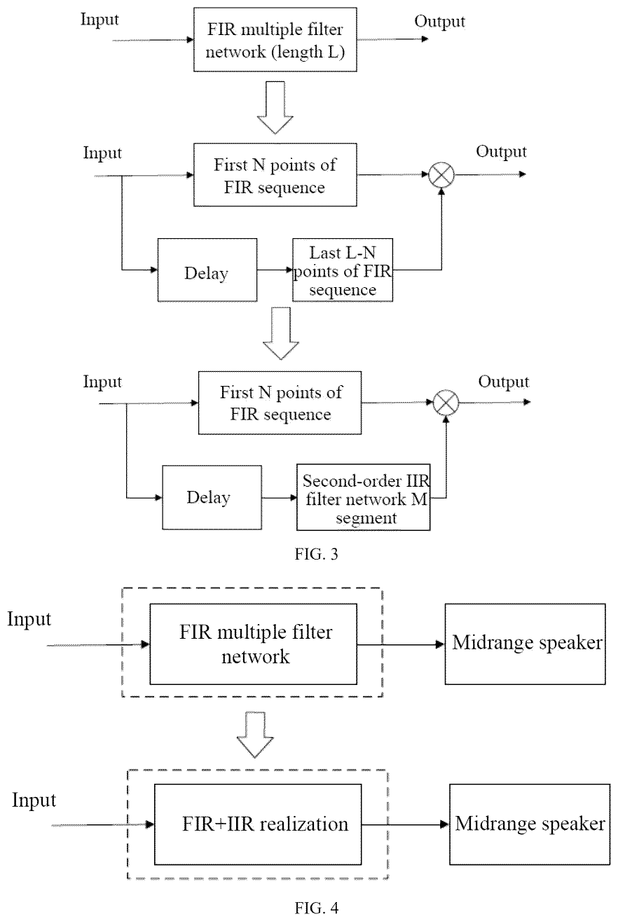

As shown in FIG. 3, for the obtained FIR multiple filter network, first N points of a FIR sequence of the FIR multiple filter network are intercepted to obtain a new FIR filter in the embodiments of the present disclosure. A length of the FIR sequence of the FIR multiple filter network is L, and N and L are both positive integers. And then an infinite impulse response (IIR) network is employed to fit last L-N points of the FIR sequence of the FIR multiple filter network. The new FIR filter and the IIR network collectively accomplish equivalent filtering of the FIR sequence of the FIR multiple filter network. The IIR network includes cascaded second-order IIR or parallel second-order IIR.

In embodiments of the present disclosure, the selection of the number of points N is generally determined based on characteristics of the FIR sequence of the FIR multiple filter network, and the N satisfies the following requirements: with respect to the first N points of the intercepted FIR sequence, a retained high-frequency component of the FIR sequence of the FIR multiple filter network satisfying a first predetermined condition; and with respect to the last L-N points of the FIR sequence, a retained low-frequency component of the FIR sequence of the FIR multiple filter network satisfying a second predetermined condition.

The first predetermined condition is configured to indicate that vast majority of high-frequency components are retained, and the second predetermined condition is configured to indicate that vast majority of low-frequency components are retained. The design of the first predetermined condition and the second predetermined condition is able to be flexibly set according to actual needs, which is not limited in the present disclosure.

In embodiments of the present disclosure, in principle, the intercepted first N-points of the FIR sequence retain more of the high-frequency components of the FIR sequence of the FIR multiple filter network, and the L-N-points of the FIR sequence retain more of the low-frequency components of the FIR sequence of the FIR multiple filter network, which allows for a better equivalent restoration using the IIR filter network. Generally, for an original speaker IR response sequence with a length greater than 10000 points, when N is selected to be 100 points or less, remaining portions of the IR are able to be fitted with a cascaded or parallel second-order IIR network with 20 segments or less, and the lower-order FIR sequence cooperating with the IIR network together is not only able to be equivalent to the processing effect with the FIR multiple filter network, but also able to reduce the computation amount to a large extent.

Furthermore, for in-vehicle or other scenarios with assigned speakers, different speakers in the array are actually designed to operate in different frequency bands. The embodiments in the present disclosure are further improved in combination with crossover filtering on the basis of the above offline processing method.

The FIR multiple filter network obtained by using the offline merging method in the embodiments of the present disclosure includes a combination of a series of FIR filters, each FIR filter corresponds to an output channel, and data of each output channel is ultimately given to a speaker connected to this output channel. In the existing technology, a type of the speaker connected to each output channel is not considered when designing the FIR multiple filter network.

In response to this, embodiments of the present disclosure further simplify the filter for each output channel by taking into account the characteristics of the speakers connected to each output channel. For a woofer speaker, only the IIR portion is retained, for a tweeter speaker, only the FIR portion is retained, and for a midrange speaker, both the FIR and IIR portions are required to be retained, thereby further reducing the computation amount.

Specifically, an offline processing mode of the FIR multiple filter network is determined based on the type of the speaker to which the audio channel is connected. The type of the speaker includes a midrange speaker, a woofer/subwoofer speaker and a tweeter speaker.

1. When the audio channel is connected to the midrange speaker, the audio channel processing needs to retain a certain amount of low-and mid-frequency information, at this time, the FIR multiple filter network is converted offline into a form of a FIR filter+IIR filter network to reduce the computation amount of real-time processing, as shown in FIG. 4.

2. When the audio channel is connected to the woofer/subwoofer speaker, only low-frequency components of the audio signal need to be ultimately given by the audio channel to the speaker. Therefore, offline low-pass filtering is performed on a FIR filter corresponding to a woofer channel in the FIR multiple filter network to retain only the low-frequency components, and then only the cascaded or parallel second-order IIR filter network is used for fitting, thus further reducing computation amount of the channel filtering, as shown in FIG. 5.

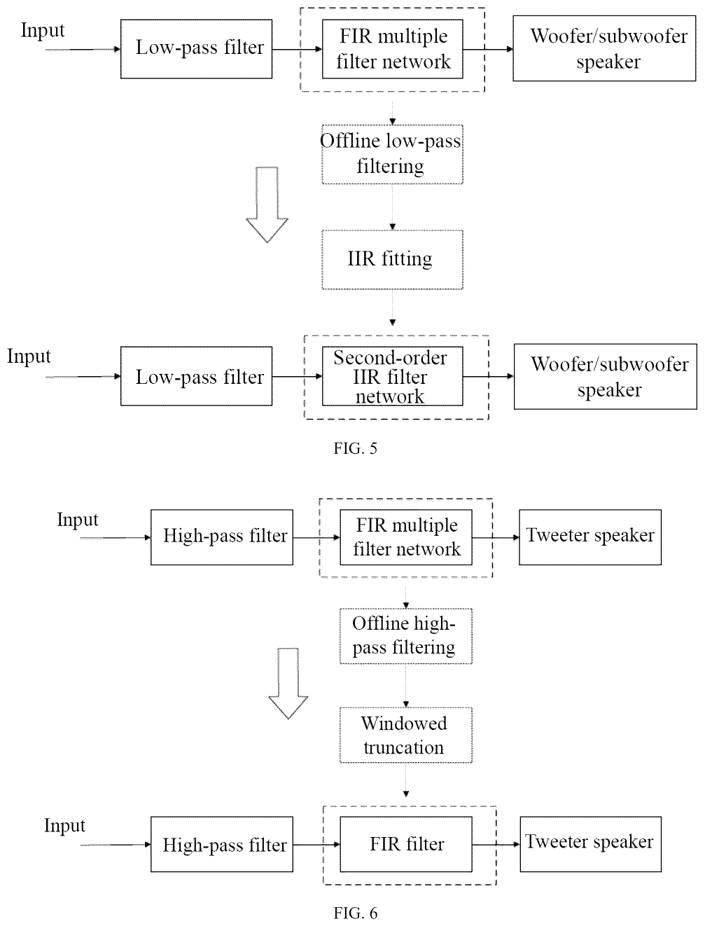

3. When the audio channel is connected to the tweeter speaker, only high-frequency components of the audio signal need to be ultimately given by the audio channel to the speaker. Therefore, offline high-pass filtering is performed on a FIR filter corresponding to a tweeter channel in the FIR multiple filter network to retain only the high-frequency components. In this way, an effective length of the FIR filter is greatly reduced, and the computation amount is effectively reduced by the windowed truncation to retain the effective high-frequency components, as shown in FIG. 6.

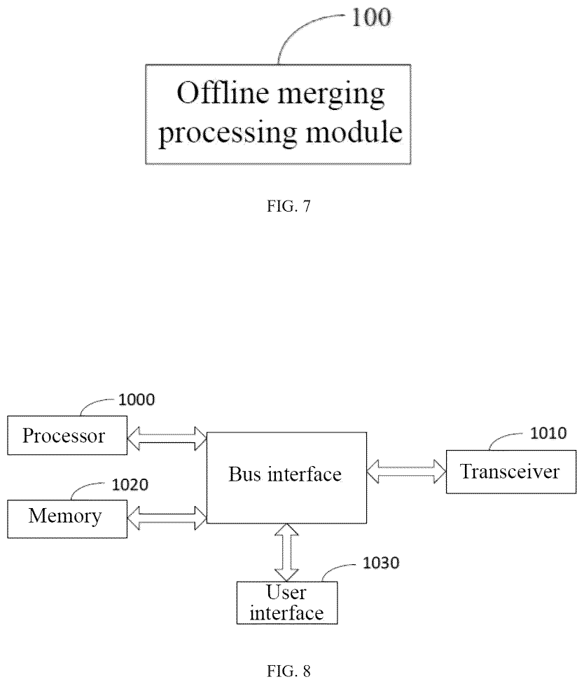

Based on the method for realizing a speaker array-oriented multiple filter system provided in the embodiments of the present disclosure, the embodiments of the present disclosure further provide an apparatus for realizing a speaker array-oriented multiple filter system, as shown in FIG. 7, which includes an offline merging processing module 100 for merging filters of a plurality of sound effect modules in an audio signal processing flow offline to form a FIR multiple filter network before real-time audio processing.

Alternatively, the apparatus for realizing the speaker array-oriented multiple filter system further includes: a first processing module for intercepting, with respect to the FIR multiple filter network, first N points of a FIR sequence of the FIR multiple filter network to obtain a new FIR filter, where the FIR sequence of the FIR multiple filter network has a length of L, and N and L are both positive integers; and a second processing module for employing an infinite impulse response (IIR) network to fit last L-N points of the FIR sequence of the FIR multiple filter network; where the new FIR filter and the IIR network collectively accomplish equivalent filtering of the FIR sequence of the FIR multiple filter network.

Alternatively, the N is determined based on characteristics of the FIR sequence of the FIR multiple filter network, and the N satisfies the following requirements: with respect to the intercepted first N points of the FIR sequence, retained high-frequency components of the FIR sequence of the FIR multiple filter network satisfying a first predetermined condition; with respect to the L-N points of the FIR sequence, retained low-frequency components of the FIR sequence of the FIR multiple filter network satisfying a second predetermined condition.

Alternatively, the IIR network includes cascaded second-order IIR or parallel second-order IIR.

Alternatively, apparatus for realizing the speaker array-oriented multiple filter system further includes a third processing module for determining an offline processing mode of the FIR multiple filter network based on a type of a speaker connected to an audio channel.

Specifically, the type of the speaker includes a midrange speaker, a woofer-subwoofer speaker and a tweeter speaker, and the third processing module is configured to: convert the FIR multiple filter network offline into a form of a FIR filter+IIR filter network in response to the audio channel being connected to the midrange speaker; perform offline low-pass filtering on a FIR filter corresponding to a woofer channel in the FIR multiple filter network and use a cascaded or parallel second-order IIR filter network for fitting in response to the audio channel being connected to the woofer/subwoofer speaker; and perform offline high-pass filtering and windowed truncation on a FIR filter corresponding to a tweeter channel in the FIR multiple filter network in response to the audio channel being connected to the tweeter speaker.

Alternatively, in the embodiments of the present disclosure, the plurality of sound effect modules include at least one of a sound field control module, an independent sound zone control module, a convolution reverb module, and a speaker compensation module.

It should be noted that the apparatus for realizing the speaker array-oriented multiple filter system is an apparatus corresponding to the method for realizing the speaker array-oriented multiple filter system in the foregoing embodiments, and all of the means for realizing the method embodiments described above are applicable to the embodiments of the apparatus for realizing the speaker array-oriented multiple filter system, and the same technical effect is also achieved.

As shown in FIG. 8, embodiments of the present disclosure further provide a device including: a processor 1000, a transceiver 1010, and a memory 1020 connected to the processor 1000 via a bus interface. The memory 1020 is configured to store programs and data used by the processor 1000 in performing operations, and the processor 1000 calls and executes the programs and data stored in the memory 1020.

The transceiver 1010 is connected to the bus interface for receiving and sending data under the control of the processor 1000, and the processor 1000 is configured to read the programs in the memory 1020 to implement the following operation: merging, before real-time audio processing, filters of a plurality of sound effect modules in an audio signal processing flow offline to form a finite impulse response (FIR) multiple filter network.

Alternatively, the method further includes: intercepting, with respect to the FIR multiple filter network, first N points of a FIR sequence of the FIR multiple filter network to obtain a new FIR filter, where the FIR sequence of the FIR multiple filter network has a length of L, and N and L are both positive integers; and employing an infinite impulse response (IIR) network to fit last L-N points of the FIR sequence of the FIR multiple filter network; where the new FIR filter and the IIR network collectively accomplish equivalent filtering of the FIR sequence of the FIR multiple filter network.

Alternatively, the N is determined based on characteristics of the FIR sequence of the FIR multiple filter network, and the N satisfies the following requirements: with respect to the first N points of the FIR sequence, retained high-frequency components of the FIR sequence of the FIR multiple filter network satisfying a first predetermined condition; and with respect to the last L-N points of the FIR sequence, retained low-frequency components of the FIR sequence of the FIR multiple filter network satisfying a second predetermined condition.

Alternatively, the IIR network includes cascaded second-order IIR or parallel second-order IIR.

Alternatively, the method further includes: determining an offline processing mode of the FIR multiple filter network based on a type of a speaker to which an audio channel is connected.

Alternatively, the type of the speaker includes a midrange speaker, a woofer-subwoofer speaker and a tweeter speaker; and the determining the offline processing mode of the FIR multiple filter network based on the type of the speaker to which the audio channel is connected includes: in response to the audio channel being connected to the midrange speaker, converting the FIR multiple filter network offline into a form of a FIR filter plus a IIR filter network; in response to the audio channel being connected to the woofer-subwoofer speaker, performing offline low-pass filtering on a FIR filter corresponding to a woofer channel in the FIR multiple filter network, and using a cascaded or parallel second-order IIR filter network for fitting; and in response to the audio channel being connected to the tweeter speaker, performing offline high-pass filtering and windowed truncation on a FIR filter corresponding to a tweeter channel in the FIR multiple filter network.

Alternatively, the plurality of sound effect modules includes at least one of a sound field control module, an independent sound zone control module, a convolution reverb module, and a speaker compensation module.

In FIG. 8, a bus structure includes any number of interconnected buses and bridges, specifically linking together various circuits of one or more processors, represented by processor 1000, and memory, represented by memory 1020. The bus structure may also link together various other circuits such as peripherals, voltage regulators, and power management circuits, all of which are well known in the art and, therefore, are not further described herein. The bus interface provides the interface. The transceiver 1010 may include a plurality of elements, i.e., including a transmitter and a receiver, providing units for communicating with a variety of other devices on a transmission medium. For different terminals, a user interface 1030 may also be an interface capable of externally and internally connecting desired devices, and the connected devices include, but not limited to, keypads, monitors, speakers, microphones, joysticks, and the like. The processor 1000 is responsible for managing the bus structure and usual processing, and the memory 1020 may store data used by the processor 1000 in performing operations.

It should be appreciated by those skilled in the art that all or some of the operations for realizing the above embodiments may be accomplished by hardware, or may be accomplished by a computer program that instructs the relevant hardware to do so. The computer program includes instructions for carrying out some or all of the operations of the above method, and the computer program is stored in a readable storage medium, which may be any form of storage medium.

In addition, embodiments of the present disclosure also provide a non-transitory computer-readable storage medium storing a computer program that, when executed by a processor, causes the processor to perform the method for realizing the speaker array-oriented multiple filter system and achieves the same technical effect, which is not repeated herein to avoid repetition.

The above description is preferred embodiments of the present disclosure, and it should be noted that for a person of ordinary skill in the art, several improvements and refinements may be made without departing from the principles described in the present disclosure, and these improvements and refinements shall also be considered as the protection scope of the present disclosure.

What is claimed is:

1. A method for realizing a speaker array-oriented multiple filter system, comprising:
merging, before real-time audio processing, filters of a plurality of sound effect modules in an audio signal processing flow offline to form a finite impulse response (FIR) multiple filter network.

2. The method according to claim 1, further comprising:
intercepting, with respect to the FIR multiple filter network, first N points of a FIR sequence of the FIR multiple filter network to obtain a new FIR filter, wherein the FIR sequence of the FIR multiple filter network has a length of L, and wherein N and L are both positive integers; and
employing an infinite impulse response (IIR) network to fit last L-N points of the FIR sequence of the FIR multiple filter network;
wherein the new FIR filter and the IIR network collectively accomplish equivalent filtering of the FIR sequence of the FIR multiple filter network.

3. The method according to claim 2, wherein the N is determined based on characteristics of the FIR sequence of the FIR multiple filter network, and the N satisfies following requirements:
with respect to the first N points of the FIR sequence, retained high-frequency components of the FIR sequence of the FIR multiple filter network satisfying a first predetermined condition; and
with respect to the last L-N points of the FIR sequence, retained low-frequency components of the FIR sequence of the FIR multiple filter network satisfying a second predetermined condition.

4. The method according to claim 2, wherein the IIR network includes cascaded second-order IIR or parallel second-order IIR.

5. The method according to claim 1, further comprising:
determining an offline processing mode of the FIR multiple filter network based on a type of a speaker to which an audio channel is connected.

6. The method according to claim 5, wherein the type of the speaker includes a midrange speaker, a woofer-subwoofer speaker and a tweeter speaker; and wherein the determining the offline processing mode of the FIR multiple filter network based on the type of the speaker to which the audio channel is connected includes:
in response to the audio channel being connected to the midrange speaker, converting the FIR multiple filter network offline into a form of a FIR filter plus a IIR filter network;
in response to the audio channel being connected to the woofer-subwoofer speaker, performing offline low-pass filtering on a FIR filter corresponding to a woofer channel in the FIR multiple filter network, and using a cascaded or parallel second-order IIR filter network for fitting; and
in response to the audio channel being connected to the tweeter speaker, performing offline high-pass filtering and windowed truncation on a FIR filter corresponding to a tweeter channel in the FIR multiple filter network.

7. The method according to claim 1, wherein the plurality of sound effect modules includes at least one of a sound field control module, an independent sound zone control module, a convolution reverb module, and a speaker compensation module.

8. A device comprising: a transceiver, a memory, a processor and a computer program stored on the memory and executable on the processor, wherein the processor executes the computer program to perform a method for realizing a speaker array-oriented multiple filter system; wherein the method includes: merging, before real-time audio processing, filters of a plurality of sound effect modules in an audio signal processing flow offline to form a finite impulse response (FIR) multiple filter network.

9. The device according to claim 8, wherein the method further includes:
intercepting, with respect to the FIR multiple filter network, first N points of a FIR sequence of the FIR multiple filter network to obtain a new FIR filter, wherein the FIR sequence of the FIR multiple filter network has a length of L, and wherein N and L are both positive integers; and
employing an infinite impulse response (IIR) network to fit last L-N points of the FIR sequence of the FIR multiple filter network;
wherein the new FIR filter and the IIR network collectively accomplish equivalent filtering of the FIR sequence of the FIR multiple filter network.

10. The device according to claim 9, wherein the N is determined based on characteristics of the FIR sequence of the FIR multiple filter network, and the N satisfies following requirements:
with respect to the first N points of the FIR sequence, retained high-frequency components of the FIR sequence of the FIR multiple filter network satisfying a first predetermined condition; and
with respect to the last L-N points of the FIR sequence, retained low-frequency components of the FIR sequence of the FIR multiple filter network satisfying a second predetermined condition.

11. The device according to claim 9, wherein the IIR network includes cascaded second-order IIR or parallel second-order IIR.

12. The device according to claim 8, wherein the method further includes:
determining an offline processing mode of the FIR multiple filter network based on a type of a speaker to which an audio channel is connected.

13. The device according to claim 12, wherein the type of the speaker includes a midrange speaker, a woofer-subwoofer speaker and a tweeter speaker; and wherein the determining the offline processing mode of the FIR multiple filter network based on the type of the speaker to which the audio channel is connected includes:
in response to the audio channel being connected to the midrange speaker, converting the FIR multiple filter network offline into a form of a FIR filter plus a IIR filter network;
in response to the audio channel being connected to the woofer-subwoofer speaker, performing offline low-pass filtering on a FIR filter corresponding to a woofer channel in the FIR multiple filter network, and using a cascaded or parallel second-order IIR filter network for fitting; and
in response to the audio channel being connected to the tweeter speaker, performing offline high-pass filtering and windowed truncation on a FIR filter corresponding to a tweeter channel in the FIR multiple filter network.

14. The device according to claim 8, wherein the plurality of sound effect modules includes at least one of a sound field control module, an independent sound zone control module, a convolution reverb module, and a speaker compensation module.

15. A non-transitory computer-readable storage medium storing a computer program, wherein the computer program when executed by a processor causes the processor to perform a method for realizing a speaker array-oriented multiple filter system; wherein the method includes: merging, before real-time audio processing, filters of a plurality of sound effect modules in an audio signal processing flow offline to form a finite impulse response (FIR) multiple filter network.

16. The non-transitory computer-readable storage medium according to claim 15, wherein the method further includes:
intercepting, with respect to the FIR multiple filter network, first N points of a FIR sequence of the FIR multiple filter network to obtain a new FIR filter, wherein the FIR sequence of the FIR multiple filter network has a length of L, and wherein N and L are both positive integers; and
employing an infinite impulse response (IIR) network to fit last L-N points of the FIR sequence of the FIR multiple filter network;
wherein the new FIR filter and the IIR network collectively accomplish equivalent filtering of the FIR sequence of the FIR multiple filter network.

17. The non-transitory computer-readable storage medium according to claim 16, the N is determined based on characteristics of the FIR sequence of the FIR multiple filter network, and the N satisfies following requirements:
with respect to the first N points of the FIR sequence, retained high-frequency components of the FIR sequence of the FIR multiple filter network satisfying a first predetermined condition; and
with respect to the last L-N points of the FIR sequence, retained low-frequency components of the FIR sequence of the FIR multiple filter network satisfying a second predetermined condition.

18. The non-transitory computer-readable storage medium according to claim 16, wherein the IIR network includes cascaded second-order IIR or parallel second-order IIR.

19. The non-transitory computer-readable storage medium according to claim 15, wherein the method further includes:
determining an offline processing mode of the FIR multiple filter network based on a type of a speaker to which an audio channel is connected.

20. The non-transitory computer-readable storage medium according to claim 19, wherein the type of the speaker includes a midrange speaker, a woofer-subwoofer speaker and a tweeter speaker; and wherein the determining the offline processing mode of the FIR multiple filter network based on the type of the speaker to which the audio channel is connected includes:
in response to the audio channel being connected to the midrange speaker, converting the FIR multiple filter network offline into a form of a FIR filter plus a IIR filter network;
in response to the audio channel being connected to the woofer-subwoofer speaker, performing offline low-pass filtering on a FIR filter corresponding to a woofer channel in the FIR multiple filter network, and using a cascaded or parallel second-order IIR filter network for fitting; and
in response to the audio channel being connected to the tweeter speaker, performing offline high-pass filtering and windowed truncation on a FIR filter corresponding to a tweeter channel in the FIR multiple filter network.
